(19) United States
(12) Patent Application Publication
(10) Pub. No.: US 2013/0154456 A1
(43) Pub. Date: Jun. 20, 2013

(54) HOUSING FOR A MONITOR WITH OR WITHOUT A KEYBOARD

(71) Applicants: Hans Haase, Sonsbeck (DE); Thomas Zimmer, Immensee (CH)

(72) Inventors: Hans Haase, Sonsbeck (DE); Thomas Zimmer, Immensee (CH)

(21) Appl. No.: 13/513,360

(22) PCT Filed: Dec. 2, 2010
(86) PCT No.: PCT/EP10/07324

§ 371 Date: Jan. 17, 2013

(30) Foreign Application Priority Data
Dec. 2, 2009 (DE) 20-2009-016312.1

(51) Int. Cl. H05K 5/06

(52) U.S. Cl. CPC H05K 5/06
USPC 312/223.2

(57) ABSTRACT

The invention comprises a shell-like upper housing part and a shell-like lower housing part. The two-part housing is formed such that it can be sealed tightly against any external environmental influences (gases, vapors, moisture, liquids, dust, chemicals and bacteria) without any ventilation to dissipate the heat developed in the housing. The two-part housing is formed completely without any rim on the outside and has a continuously smooth, joint-free surface, which is designed such that it can be sealed with a coating in the nanometre range that repels contamination and bacteria.

The present invention relates to a housing for an electronic device, in particular a personal computer (all-in-one PC) or a screen or monitor, with or without a keypad or keyboard.

Computer-assisted or computer-controlled displays and/or operating and control devices are currently very widespread and used in nearly all fields, wherein the devices are used in particular for purposes of operation, control, communication, data processing, data evaluation, etc. Such devices are often also used in particular in environments where it is desirable and necessary to protect the devices, especially against moisture, dirt and aggressive chemicals. In particular, this includes the use of such devices in gastronomy, and especially in the fast food industry, in restaurants and commercial kitchens, wherein such devices are here used in particular as cash registers, ordering systems, and for communications applications. Additional examples of applications for such devices in which the devices are exposed to high loads based on their environment include the pharmaceutical/chemical industry and their production facilities and laboratories, and very generally in processing industries and in machines used in the open air.

In general, the plurality of applications can be divided into fields that require a high level of hygiene, such as gastronomy, and also in pharmaceutical/chemical industries and at hospitals and sanitariums, wherein it is desirable to provide the imagers and displays and/or operating and control devices in an easy-to-clean housing that is protected to the greatest extent possible against contamination, and can be easily and thoroughly cleaned. On the other hand, there are also applications that require that the displays and/or operating and control devices be provided in a housing, and protected to the greatest possible extent against damaging influences from their environment, which also include use in gastronomy and the pharmaceutical/chemical industry, and, for example, use as well in outside operations at construction sites, etc., wherein it is desirable to protect the devices against damaging influences such as dust, fumes, dirt, moisture, etc.

Therefore, the object of the invention is to indicate a housing of the kind mentioned at the outset, which is more reliably protected against environmental influences, such as gases, vapors, moisture, liquid, dusts (e.g., flour dust in commercial bakeries), chemicals and also bacteria, and whose exterior is easy to clean even with grease-removing detergents, wherein scratches in the housing surface are largely avoided via fine lubricating gel additives in cleaning liquids or rough cleaning sponges or cleaning rags.

The object is essentially achieved according to the invention by virtue of the fact that the housing composed of a shell-like upper housing part and a shell-like lower housing part and tightly sealable against external environmental influences without any ventilation to dissipate the heat developed out of the housing interior is formed without a rim on the outside and has a continuously smooth, joint-free surface, which is designed to be sealed with thin, protectively repellant coating in the nanometer range.

Exemplary embodiments according to the invention may be gleaned from the subclaims and/or the following description in conjunction with a drawing, without any limitation whatsoever being placed on the invention.

Diagrammatically shown on the drawing is:

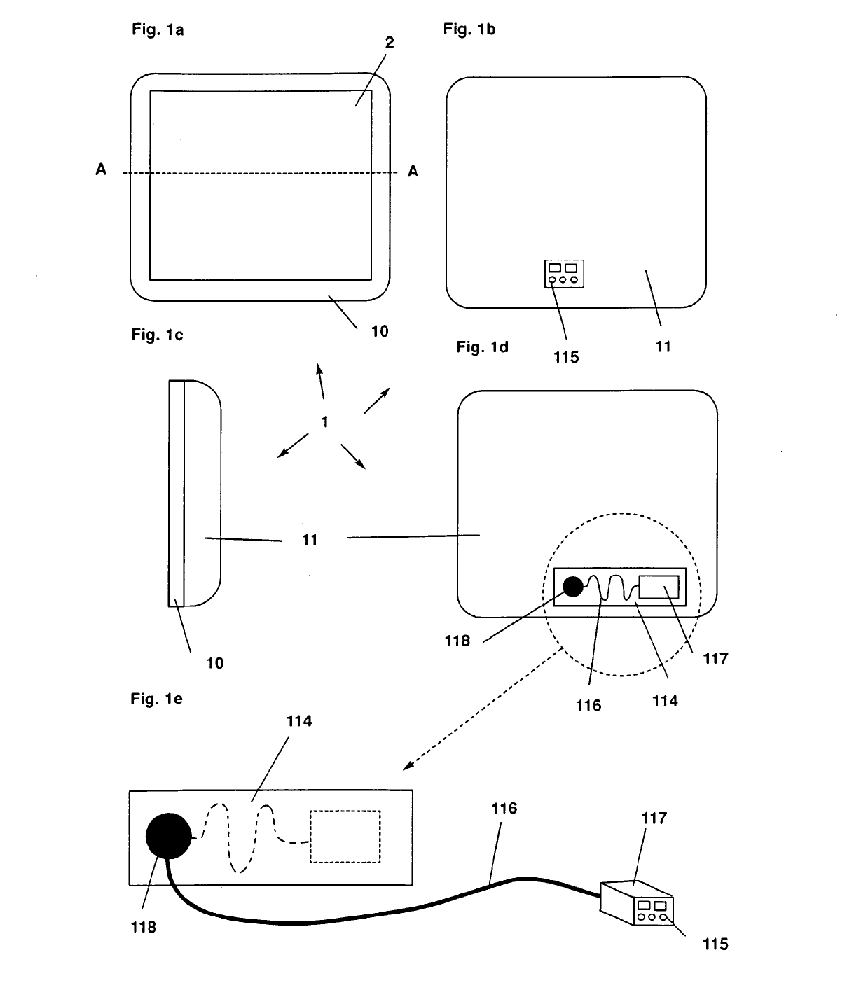

FIG. 1:

FIG. 1a A top view of a two-part housing according to the invention;

FIG. 1b A rear view of the housing;

FIG. 1c A side view of the housing;

FIG. 1d Another exemplary rear view of the housing;

FIG. 1e A magnified partial view from FIG. 1d.

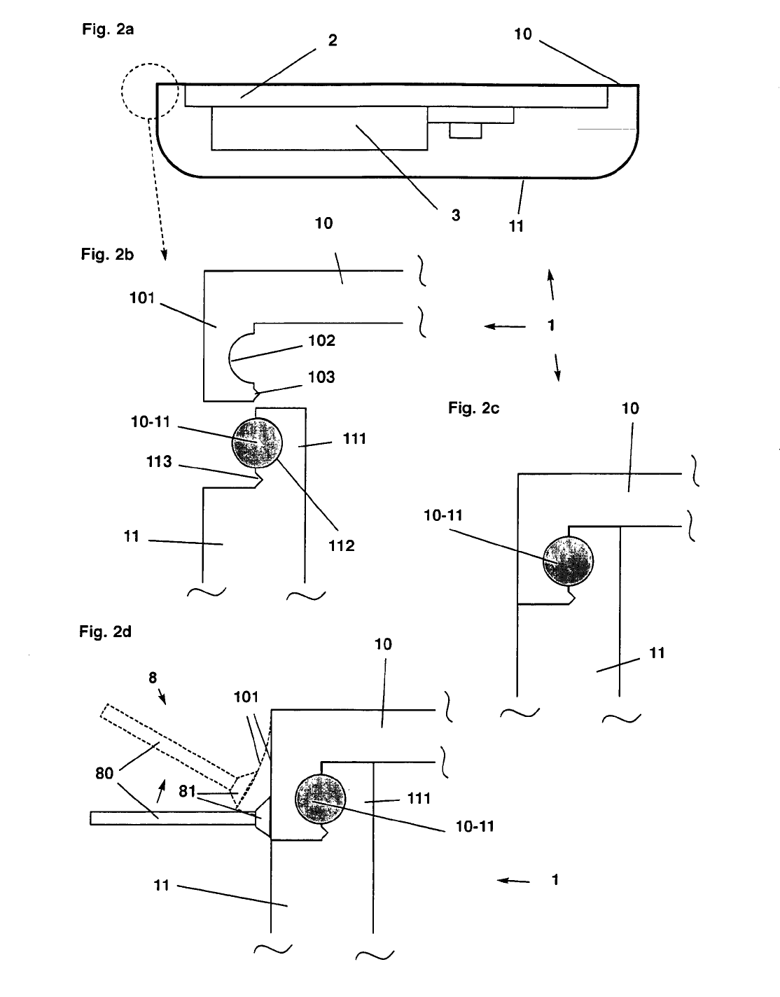

FIG. 2:

FIG. 2a A perpendicular section through the two-part housing along line A-A on FIG. 1a;

FIG. 2b Partial views of the two housing parts in positions separated from each other;

FIG. 2c The partial views of the two housing parts according to FIG. 2b in a positively joined position, and

FIG. 2d The partial view according to FIG. 1c in the position for removing the upper housing part from the lower housing part.

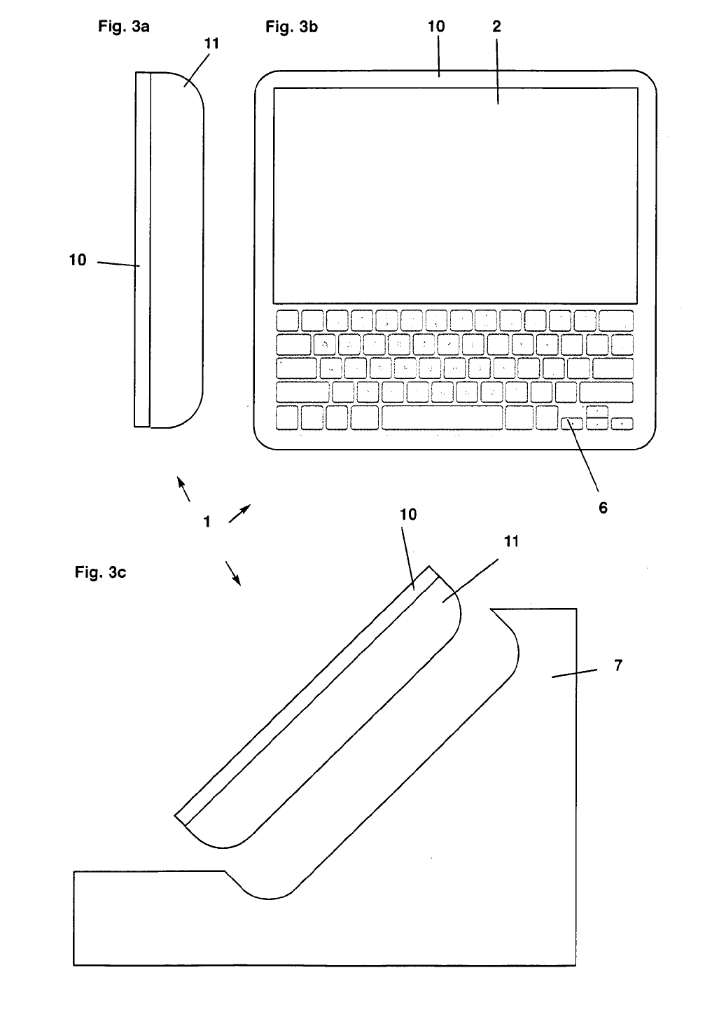

FIG. 3:

FIG. 3a A side view of the housing according to the invention on FIG. 1c;

FIG. 3b A top view of the transparent upper housing part;

FIG. 3c A perpendicular section through an inductive charging station for an all-in-one PC in the housing according to FIGS. 1 and 2;

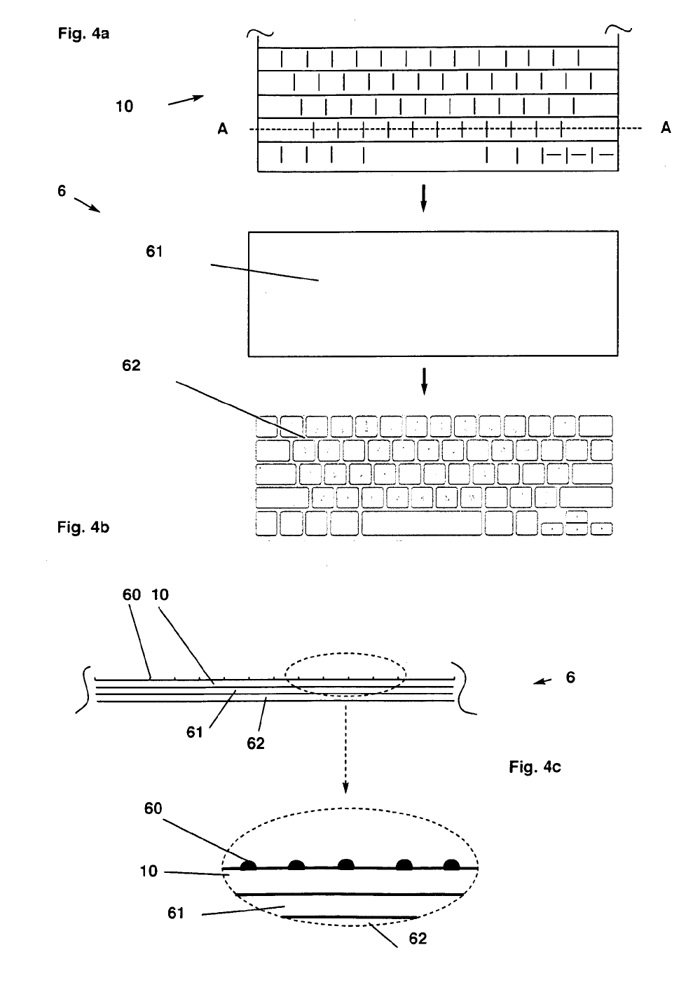

FIG. 4:

FIG. 4a A diagrammatic, magnified drawing of a keyboard in the housing below a transparent partial region of the upper housing part on FIG. 3b;

FIG. 4b A perpendicular section in the area of sectional line A-A on FIG. 4a;

FIG. 4c A magnified section from FIG. 4b;

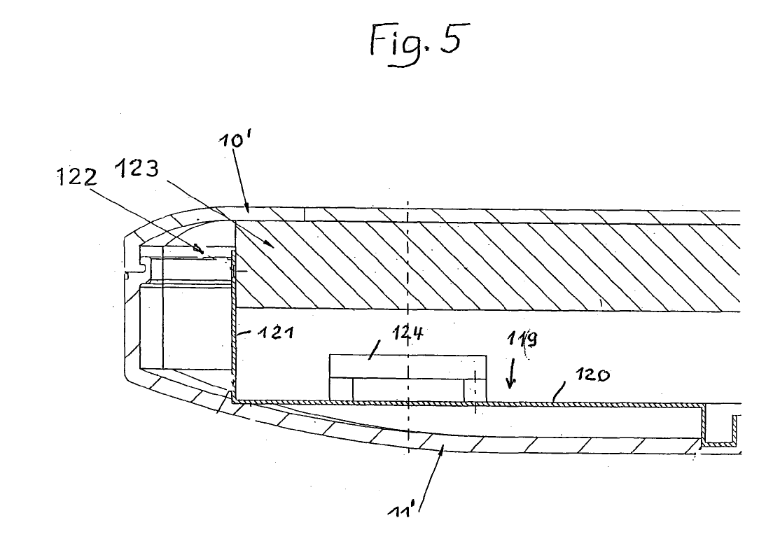

FIG. 5: A perpendicular partial section through a housing according to the invention, with an all-in-one PC secured to the upper housing part, or only a monitor;

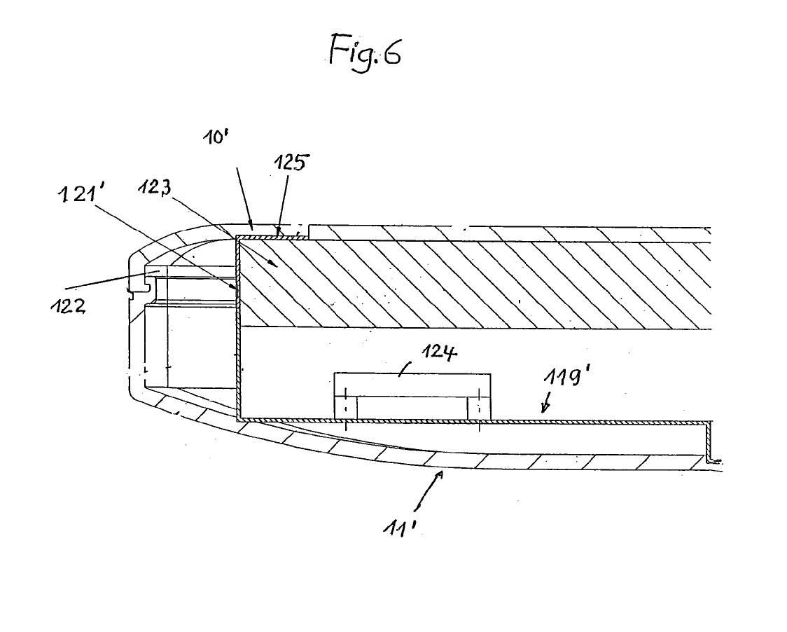

FIG. 6: A perpendicular partial section through a housing according to the invention with an all-in-one PC secured to the upper housing part, or only a monitor.

FIG. 1a shows a diagrammatic top view of a housing according to the invention in a first embodiment of the present invention with a shell-like upper housing part 10, which is at least partially transparent in design, and underneath which is situated a screen 2. FIG. 1b shows the housing 1 from FIG. 1a with the shell-like lower housing part 11 from the back, which accommodates I-O ports 115 that allow hardware located inside the housing 1 to be connected with external devices, and FIG. 1c presents a side view of the housing 1 from FIG. 1a with the shall-like lower housing part 11 and the shell-like upper housing part 10. A window (not shown in the drawings) for an optical device, such as a bar code scanner, can also be provided at a suitable position of the shell-like lower housing part 11.

FIG. 1d shows an advantageous modification of the shell-like lower housing part 11 that incorporates a recess 114 provided with a removable cover, which accommodates a removable connection box 117 that in turn encompasses a plurality of I-O ports, and which is linked via an external cable 116 with the hardware and/or software situated in the housing 1 through a hole in the recess 114. It is here also advantageous to provide a gasket 118 tailored precisely to the hole and external cable 116, which hermetically seals the hole and prevents any and all bacteria or dirt from accumulating on the hole. FIG. 1e shows a magnified, diagrammatic depiction of the recess 114 in the shell-like lower housing part 11 with the gasket 118 and the connection box 117 accommodating the I-O ports, which is removed from the recess 114, and connected with the hardware situated inside the housing 1 by means of a cable 116 through the hole, wherein the hole and cable 116 can be completely sealed off via the gasket 118.

FIG. 2a shows a diagrammatic section through the housing 1 on FIG. 1a along line A-A on FIG. 1a, with the shell-like upper housing part 10, the shell-like lower housing part 11, and the screen 2 arranged inside the housing 1, along with other electronics 3 situated inside the housing 1.

FIG. 2b shows a magnified partial view of the housing 1 on FIG. 2a in an open state, with the shell-like upper housing part 10, which accommodates a continuous rim 101 with a sealing profile 102 and lock profile 103, and with the shell-like lower housing part 11, whose continuous rim 111 accommodates a lock profile 112 and a lock 113, which each correspond with the sealing profile 102 and lock profile 103 of the outer continuous rim 101 of the shell-like upper housing part 10, and with a gasket 10-11 situated in the sealing profile 112 of the shell-like lower housing part 11.

FIG. 2c shows the cutout of housing 1 on FIG. 2b in the closed state, with the shell-like upper housing part 10 and shell-like lower housing part 11 and the sealing profile 102, 112 that is provided between the rims 101 and 111 of the shell-like upper housing part 10 and shell-like lower housing part 11 and incorporates the gasket 10-11, and with the lock profile 103 of the shell-like upper housing part 10 latched with the lock 113 of the shell-like lower housing part 11, and FIG. 2d shows the diagrammatic view of FIG. 2c to include a suitable tool 8 for easily opening and closing the housing 1, for example, which can be designed as a plunger 8 with a rod 80 and suction cup 81, wherein the plunger 8 is held fast by suction against the elastic, continuous rim 101 of the upper housing side 10, and wherein the rod 80 can be swiveled to outwardly divert the elastic rim 101 of the upper housing side 10 from the outer rim 111 of the rear housing side 11, as a result of which the lock 113 and sealing profile 102, 112 are opened.

FIG. 3a shows a diagrammatic, side view of another advantageous embodiment of the housing 1 with the shell-like upper housing part 10 and the shell-like lower housing part 11, and FIG. 3b shows a top view of the housing 1 on FIG. 3a, with the at least partially transparent, shell-like upper housing part 10, underneath which a screen 2 along with a keyboard 6 are arranged, and FIG. 3c shows the housing 1 from FIG. 3a in conjunction with a diagrammatic view of a base station 7, by means of which the rechargeable batteries inside the housing 1 can be wirelessly recharged via induction.

A housing 1 according to the invention in the embodiment of the present invention depicted on FIGS. 1 and 2 can only accommodate one monitor, and hence one display device, while the configuration on FIG. 3 advantageously accommodates the monitor 2 as a display device, and the keyboard 6 as the operating device, wherein the housing 1 on FIG. 1 and FIG. 3 an also incorporate other electronics 3, so that the housing 1 incorporates a control device in addition to the screen and/or operating devices. The housing 1 can suitably also have wireless interfaces for purposes of wireless communication and data transmission with external devices.

FIG. 4a shows a diagrammatic, exploded view of the keyboard 6 on FIG. 3b, with a cutout of the shell-like upper housing part 10, a capacitive-projective film 61 situated directly underneath the shell-like upper housing part 10, and with a keyboard template 62 that is located directly underneath the capacitive-projective film 61, and corresponds with the film 61. The shell-like upper housing part 10 is provided with small elevations 60 in the area of the keyboard 6, which correspond with the capacitive-projective film 61 and keyboard template 62. The elevations are arranged in such a way as to reproduce the keyboard 6 via the elevations 60 from a tactile standpoint. To this end, the projective-capacitive film 61 exists underneath the upper housing part 10, along with the keyboard template 62 or keyboard 6. FIG. 4b presents a diagrammatic view through the keyboard 6 on FIG. 4a, while FIG. 4c shows a magnified side view of FIG. 4b.

The shell-like upper housing part 10 can be designed as a single piece with a lamellar privacy filter (not shown on the drawings), which creates an angle-dependent view of the monitor 2 and/or keyboard 6, wherein one modification of the above embodiment of the lamellar privacy filter can advantageously also provide that an intermediate layer (also not shown on the drawings for the sake of simplicity) be situated between the shell-like upper housing part 10 and the monitor 2, and/or between the projective-capacitive film 61 and the keyboard template 62.

FIG. 5 provides a diagrammatic view of only the left half of an axial section through a housing according to the invention, with the shell-like upper housing part 10′ and shell-like lower housing part 11′ in embodiments modified in relation to the above figures. Adhesively bonded inside the lower housing part 11′ is a frame-shaped sheet body 119 with a floor 120 and a continuous, perpendicular rim 121, whose upper end is supported against a radially continuous housing ring 122 on the inner upper housing part 10. Detachably secured to the perpendicular rim is a monitor/screen 123 in a position which causes the upper housing part 10′ to form a tight seal against the outer surface of the monitor 123 with its transparent interior side as it tightly adjoins the lower housing part 11′. This case can also involve the monitor of a PC, which can be detachably connected to electrical controllers (hardware and software) 124 by means of an electrical cable (not shown) via plug contacts detachably fixed on the floor 120 of the sheet body. A cooling medium is placed between the floor of the sheet body and the floor of the lower housing part 11.

The right half of the housing (not shown) is a mirror image of the left half of the housing depicted here.

In the same way as FIG. 5, FIG. 6 provides a diagrammatic view of only the left half of an axial section through the housing according to the invention, with the difference that the continuous, perpendicular rim 121′ of the sheet body 119′ is lengthened up to the lower side of the shell-like upper housing part, and exhibits a carrier sheet 125 inwardly diverted at a right angle, the outside of which is detachably affixed to the interior side of the upper housing part 10′, wherein, as opposed to FIG. 5, the monitor 123 or PC is here held by the upper housing part 10′, the outer surface of which tightly adjoins the interior side of the upper housing part.

1. A housing for an electronic device, in particular a personal computer (all-in-one PC) or a screen or monitor or keyboard with or without a keypad, characterized in that the housing composed of a shell-like upper housing part and a shell-like lower housing part and tightly sealable against external environmental influences without any ventilation is formed without a rim on the outside, and has a continuously smooth, joint-free surface.

2. The housing according to claim 1, characterized in that the housing is designed to be sealed with a thin, protectively repellant coating in the nanometer range.

3. The housing according to claim 1, characterized in that the upper housing part of the housing exhibits a flat, transparent surface section that adjoins the face of the PC or screen in the housing from below.

4. The housing according to claim 1, characterized in that the upper housing part exhibits a flat, transparent surface section that adjoins the face of the PC or screen in the housing from below, and along with an adjacent second flat, transparent surface section adjoins the exterior side of the keyboard for the PC or screen from below.

5. The housing according to claim 3 or 4, characterized in that the face of the PC or screen (with or without the keypad) is situated on the lower side of the flat, transparent surface section of the upper housing part in a detachably fixed manner.

6. The housing according to claim 3 or 4, characterized in that the face of the PC or screen (with or without keypad) is detachably fixed in the lower housing part in such a way that the rear of the upper housing part adjoins the face of the PC or screen (with or without keypad) with its flat, transparent surface section.

7. The housing according to one of the preceding claims 1 to 6, characterized in that the lower housing part exhibits a dual floor, wherein a heat-absorbing means is situated in the gap between the floors.

8. The housing according to claim 7, characterized in that electronic software and/or hardware in conjunction with the screen and/or PC is detachably secured to the dual floor in the shell-like lower housing part.

9. The housing according to one of the preceding claims 1 to 8, characterized in that a continuous lateral rim on the upper housing part and a lateral continuous rim on the lower housing part are positively joined together to form a smooth, joint-free outer surface that is continuous around the housing.

10. The housing according to claim 9, characterized in that at least one annular, continuous, elastically deformable gasket is arranged between the contrary, overlapping sections on the rims on both sides of the upper and lower housing parts, which is in the junction position of the two housing parts under exposure to a sealing pre-stress.

11. The housing according to claim 10, characterized in that the detachable connection of the lateral rims on both sides of the housing parts is designed as an elastic snap-lock.

12. The housing according to one of the preceding claims, characterized in that at least the upper housing part consists of aluminum.

13. The housing according to claim 1, characterized in that the transparent section of the upper housing part can be covered with a privacy film.
